(19) United States
(12) Patent Application Publication
(10) Pub. No.: US 2025/0365987 A1
(43) Pub. Date: Nov. 27, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Hui Woo PARK, Gyeonggi-do (KR)

(21) Appl. No.: 18/826,180

(22) Filed: Sep. 6, 2024

(30) Foreign Application Priority Data
May 27, 2024 (KR) 10-2024-0068274

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511

(57) ABSTRACT

A semiconductor device may include a peripheral circuit; a first gate structure disposed on the peripheral circuit; a second gate structure disposed on the first gate structure; a dielectric bonding structure extending between the first gate structure and the second gate structure; a first contact via extending through the first gate structure and extending into the dielectric bonding structure; a second contact via extending through the second gate structure and connected to the first contact via; and a peripheral circuit bonding structure electrically connecting the first contact via and the peripheral circuit to each other.

### CROSS-REFERENCE TO RELATED APPLICATION

This application claims priority under 35 U.S.C. § 119 to Korean Patent Application No. 10-2024-0068274 filed on May 27, 2024, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been proposed.

### SUMMARY

In an embodiment of the present disclosure, a semiconductor device may include a peripheral circuit; a first gate structure disposed on the peripheral circuit; a second gate structure disposed on the first gate structure; a dielectric bonding structure extending between the first gate structure and the second gate structure; a first contact via extending through the first gate structure and extending into the dielectric bonding structure; a second contact via extending through the second gate structure and connected to the first contact via; and a peripheral circuit bonding structure electrically connecting the first contact via and the peripheral circuit to each other.

In an embodiment of the present disclosure, a manufacturing method of a semiconductor device may include forming a first cell wafer including a first gate structure and first contact vias extending through the first gate structure; forming a second cell wafer including a second gate structure and via sacrificial layers extending through the second gate structure; bonding the first cell wafer and the second cell wafer to each other; forming via openings by removing the via sacrificial layers; exposing the first contact vias by expanding the via openings; and forming second contact vias in the via openings, respectively.

These and other features and advantages of the embodiments of the present disclosure will become better understood from the following detailed description and figures.

### BRIEF DESCRIPTION OF THE DRAWINGS

FIG. 1 is a diagram describing a semiconductor device in accordance with an embodiment of the present disclosure.

FIG. 2 is a diagram describing a semiconductor device in accordance with an embodiment of the present disclosure.

FIGS. 3A and 3B, FIG. 4, FIGS. 5A to 5C, and FIGS. 6 and 7 are diagrams describing a manufacturing method of a semiconductor device in accordance with an embodiment of the present disclosure.

FIGS. 8 to 11 are diagrams describing a manufacturing method of a semiconductor device in accordance with an embodiment of the present disclosure.

FIG. 12 is a flowchart describing a manufacturing method of a semiconductor device in accordance with FIGS. 3A and 3B, FIG. 4,

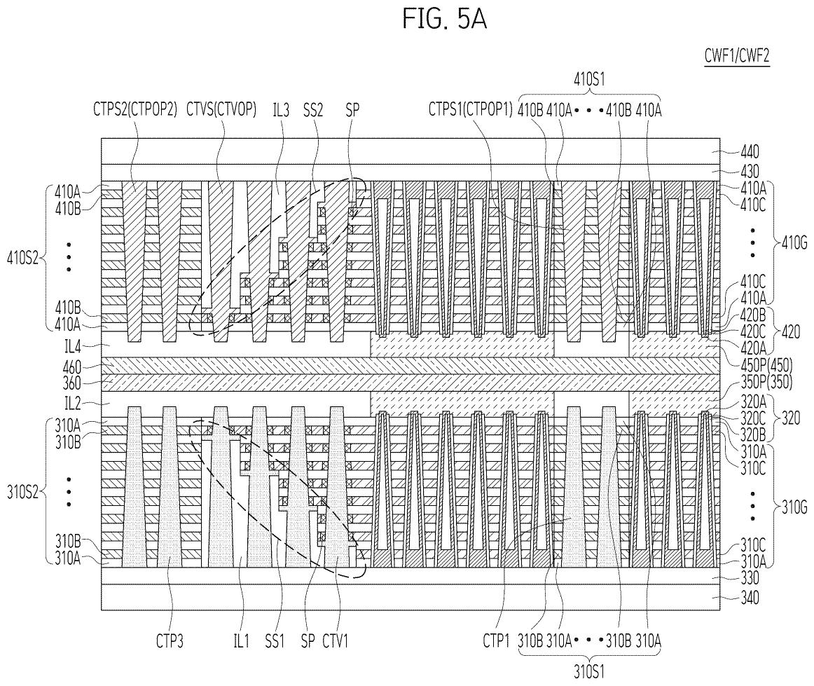

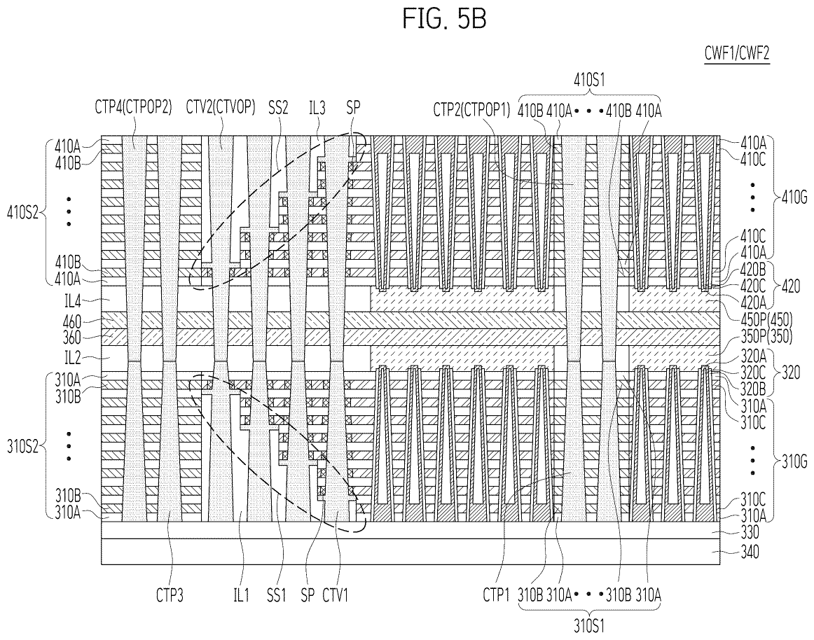

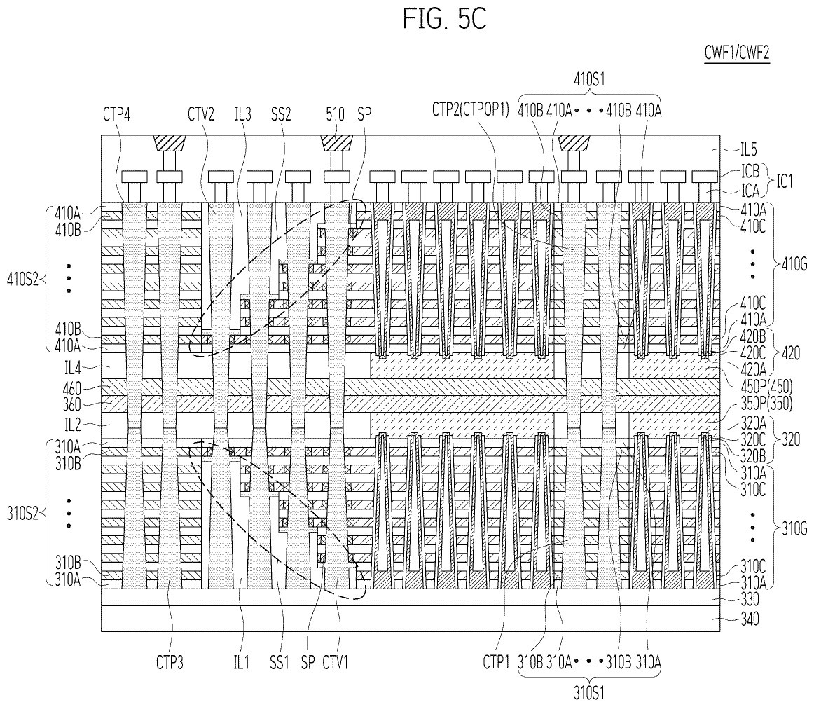

FIGS. 5A to 5C, and FIGS. 6 and 7, and FIGS. 8 to 11.

FIG. 13 is a diagram describing a memory system in accordance with an embodiment of the present disclosure.

FIG. 14 is a diagram describing a memory system in accordance with an embodiment of the present disclosure.

FIG. 15 is a diagram describing a memory system in accordance with an embodiment of the present disclosure.

FIG. 16 is a diagram describing a memory system in accordance with an embodiment of the present disclosure.

FIG. 17 is a diagram describing a memory system in accordance with an embodiment of the present disclosure.

FIG. 18 is a configuration diagram of a semiconductor device in accordance with an embodiment of the present disclosure.

### DETAILED DESCRIPTION

Various embodiments of the present disclosure are directed to a semiconductor device having a stable structure and improved characteristics and a manufacturing method of the semiconductor device.

According to the present technology, it is possible to provide a semiconductor device having a stable structure and improved reliability.

Hereafter, embodiments in accordance with the technical concepts of the present disclosure will be described with reference to the accompanying drawings.

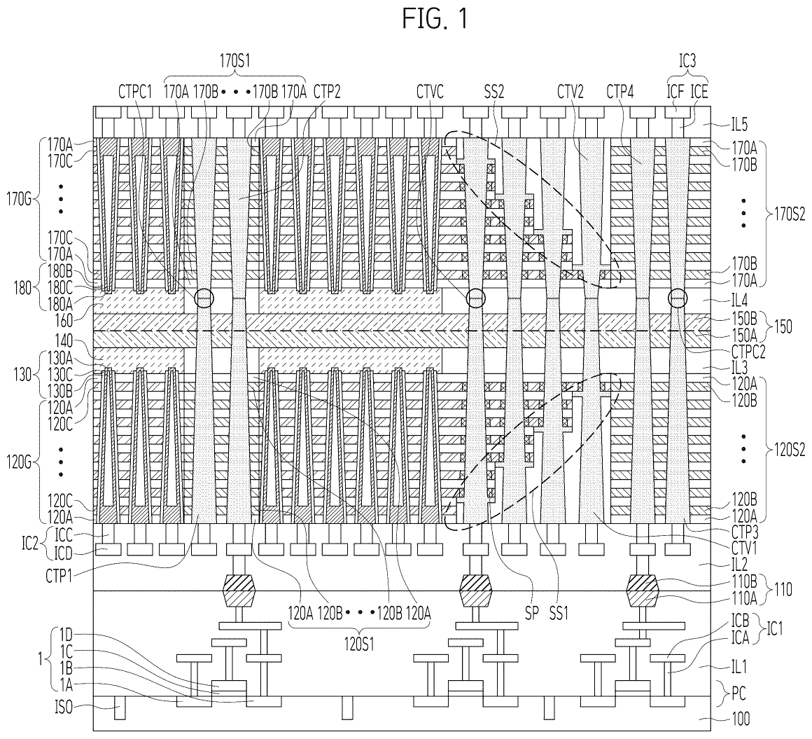

FIG. 1 is a diagram describing a semiconductor device in accordance with an embodiment of the present disclosure.

Referring to the embodiment of FIG. 1, the semiconductor device may include a substrate 100, a peripheral circuit bonding structure 110, a first stack 120S1, a third stack 120S2, a first gate structure 120G, a first channel structure 130, a first source structure 140, a dielectric bonding structure 150, a second source structure 160, a second stack 170S1, a fourth stack 170S2, a second gate structure 170G, a second channel structure 180, a first contact plug CTP1, a second contact plug CTP2, a third contact plug CTP3, a fourth contact plug CTP4, a first contact via CTV1, and a second contact via CTV2.

The semiconductor device may further include at least one of an element isolation layer ISO, a peripheral circuit PC, an insulating spacer SP, a first interconnection structure IC1, a second interconnection structure IC2, a third interconnection structure IC3, a first interlayer insulating layer IL1, a second interlayer insulating layer IL2, a third interlayer insulating layer IL3, a fourth interlayer insulating layer IL4, and a fifth interlayer insulating layer IL5.

The peripheral circuit PC may be disposed on the substrate 100. The peripheral circuit PC may include a transistor 1. For example, the peripheral circuit PC may include a page buffer and/or a row decoder. The transistor 1 may include junctions 1A and 1B, a gate electrode 1D, and a gate insulating layer 1C. Here, the gate insulating layer 1C may be disposed between the gate electrode 1D and the substrate 100. The element isolation layer ISO may be disposed in the substrate 100, and an active region may be defined by the element isolation layer ISO. The transistor 1 may be disposed in the active region.

The first interconnection structure IC1 may be disposed on the substrate 100. The first interconnection structure IC1 may be disposed in the first interlayer insulating layer IL1. Here, the first interlayer insulating layer IL1 may be disposed on the substrate 100. The first interconnection structure IC1 may include first vias ICA and first wiring lines ICB. The first vias ICA may extend in a direction vertical to the top surface of the substrate. The first wiring lines ICB may extend in a direction parallel to the top surface of the substrate. The first interconnection structure IC1 may be connected to the peripheral circuit PC. For example, at least one of the first vias ICA may be connected to the transistor 1. At least one of the first vias ICA may connect the first wiring lines ICB to each other. The first wiring lines ICB may connect the first vias ICA to each other. The first interconnection structure IC1 may include a conductive material such as tungsten. The first interlayer insulating layer IL1 may include an insulating material such as oxide or nitride.

The peripheral circuit bonding structure 110 may be disposed on the first interconnection structure IC1. The peripheral circuit bonding structure 110 may be electrically connected to the peripheral circuit PC through the first interconnection structure IC1. The peripheral circuit bonding structure 110 may include a first peripheral circuit bonding pad 110A and a second peripheral circuit bonding pad 110B. The first peripheral circuit bonding pad 110A and the second peripheral circuit bonding pad 110B may be directly coupled to each other. The first peripheral circuit bonding pad 110A may be disposed in the first interlayer insulating layer IL1. The second peripheral circuit bonding pad 110B may be disposed on the first peripheral circuit bonding pad 110A and disposed in the second interlayer insulating layer IL2. Here, the second interlayer insulating layer IL2 may be disposed on the first interlayer insulating layer IL1. The peripheral circuit bonding structure 110 may include a conductive material such as copper, and the second interlayer insulating layer IL2 may include an insulating material such as oxide.

The second interconnection structure IC2 may be disposed on the peripheral circuit bonding structure 110. The second interconnection structure IC2 may be disposed in the second interlayer insulating layer IL2. The second interconnection structure IC2 may include second vias ICC and second wiring lines ICD. Some of the second wiring lines ICD may be used as bit lines. For example, second wiring lines ICD connected to the first channel structures 130 among the second wiring lines ICD may be used as the bit lines. The second interconnection structure IC2 may be connected to the peripheral circuit bonding structure 110. For example, at least one of the second vias ICC may be connected to the second peripheral circuit bonding pad 110B. The second interconnection structure IC2 may include a conductive material such as tungsten. The second interlayer insulating layer IL2 may include an insulating material such as oxide or nitride.

The first gate structure 120G may be disposed over the peripheral circuit PC. The first gate structure 120G may include first insulating layers 120A and first conductive layers 120C that are alternately stacked. Here, the first conductive layers 120C may be gate lines. The gate line may include at least one of a word line, a source select line, and a drain select line.

The first gate structure 120G may include a first staircase structure SS1. For example, the first gate structure 120G may include the first staircase structure SS1 exposing an upper surface of each of the first conductive layers 120C. The first staircase structure SS1 may have an inverted shape. Here, the first insulating layers 120A may each include an insulating material such as oxide, and the first conductive layers 120C may each include a conductive material such as tungsten, polysilicon, or molybdenum.

The first stack 120S1 and the third stack 120S2 may be disposed at a level corresponding to the first gate structure 120G. The first stack 120S1 and the third stack 120S2 may each include first insulating layers 120A and first sacrificial layers 120B that are alternately stacked. The first stack 120S1 and the third stack 120S2 may be structures remaining without being replaced with the first gate structure 120G. Here, the first sacrificial layers 120B may each include a sacrificial material such as nitride.

The second gate structure 170G may be disposed over the first gate structure 120G. The second gate structure 170G may include second insulating layers 170A and second conductive layers 170C that are alternately stacked. Here, the second conductive layers 170C may be gate lines.

The second gate structure 170G may include a second staircase structure SS2. For example, the second gate structure 170G may include the second staircase structure SS2 exposing an upper surface of each of the second conductive layers 170C. The second staircase structure SS2 may have a shape in which it is symmetrical to the first staircase structure SS1. Here, the second insulating layers 170A may each include an insulating material such as oxide, and the second conductive layers 170C may each include a conductive material such as tungsten, polysilicon, or molybdenum.

The second stack 170S1 may be disposed over the first stack 120S1, and the fourth stack 17052 may be disposed over the third stack 120S2. The second stack 170S1 and the fourth stack 170S2 may each include second insulating layers 170A and second sacrificial layers 170B that are alternately stacked. The second stack 170S1 and the fourth stack 170S2 may be structures remaining without being replaced with the second gate structure 170G. Here, the second sacrificial layers 170B may each include a sacrificial material such as nitride.

The dielectric bonding structure 150 may extend between the first gate structure 120G and the second gate structure 170G. The dielectric bonding structure 150 may include a first dielectric bonding layer 150A and a second dielectric bonding layer 150B disposed on the first dielectric bonding layer 150A. In a process of manufacturing the semiconductor device, the first dielectric bonding layer 150A and the second dielectric bonding layer 150B may be directly bonded to each other. According to an embodiment of the present disclosure, the first dielectric bonding layer 150A and the second dielectric bonding layer 150B may be directly bonded to each other without forming separate bonding pads. Here, the dielectric bonding structure 150 may include a dielectric material.

The first source structure 140 may be disposed on the first gate structure 120G. The second source structure 160 may be disposed between the first source structure 140 and the second gate structure 170G. Here, the dielectric bonding structure 150 may extend between the first source structure 140 and the second source structure 160. The first source structure 140 and the second source structure 160 may each include a conductive material such as polysilicon.

The first channel structures 130 may extend into the first source structure 140 through the first gate structure 120G. Each of the first channel structures 130 may include at least one of a first channel layer 130A, a first memory layer 130B surrounding the first channel layer 130A, and a first insulating core 130C disposed in the first channel layer 130A. Here, the first channel layers 130A of the first channel structures 130 may be connected to the first source structure 140.

The second channel structures 180 may extend into the second source structure 160 through the second gate structure 170G. Each of the second channel structures 180 may include at least one of a second channel layer 180A, a second memory layer 180B surrounding the second channel layer 180A, and a second insulating core 180C disposed in the second channel layer 180A. Here, the second channel layers 180A of the second channel structures 180 may be connected to the second source structure 160.

The first contact plug CTP1 may extend through the first stack 120S1. For example, the first contact plug CTP1 may extend through the first stack 120S1 and extend into the dielectric bonding structure 150. Here, the third interlayer insulating layer IL3 may be disposed between the first stack 120S1 and the dielectric bonding structure 150. The third interlayer insulating layer IL3 may be disposed at a level corresponding to the first source structure 140.

The first contact plug CTP1 may be electrically connected to the peripheral circuit PC. For example, the first contact plug CTP1 may be electrically connected to the peripheral circuit PC through the peripheral circuit bonding structure 110. The first contact plug CTP1 may include a conductive material such as tungsten.

The second contact plug CTP2 may extend through the second stack 170S1. For example, the second contact plug CTP2 may extend through the second stack 170S1 and be connected to the first contact plug CTP1. The first contact plug CTP1 and the second contact plug CTP2 may be directly electrically connected to each other without a bonding pad interposed therebetween. Here, a first plug connection portion CTPC1 where the first contact plug CTP1 and the second contact plug CTP2 are connected to each other may be disposed over the dielectric bonding structure 150. The fourth interlayer insulating layer IL4 may be disposed between the second stack 170S1 and the dielectric bonding structure 150. The first plug connection portion CTPC1 may be disposed in the fourth interlayer insulating layer IL4. The fourth interlayer insulating layer IL4 may be disposed at a level corresponding to the second source structure 160. The second contact plug CTP2 may include a conductive material such as tungsten.

The second contact plug CTP2 may be electrically connected to the peripheral circuit PC. For example, the second contact plug CTP2 may be electrically connected to the peripheral circuit PC through the first contact plug CTP1 and the peripheral circuit bonding structure 110. Here, the second contact plug CTP2 may be connected to the page buffer.

The first contact plug CTP1 and the second contact plug CTP2 may provide a path for transmitting a bias to the bit line. For example, the first contact plug CTP1 and the second contact plug CTP2 may provide a path for transmitting a bias to a bit line connected to a memory string.

The third contact plug CTP3 may extend through the third stack 120S2 and extend into the dielectric bonding structure 150. The third contact plug CTP3 may be electrically connected to the peripheral circuit PC. For example, the third contact plug CTP3 may be electrically connected to the peripheral circuit PC through the peripheral circuit bonding structure 110. The third contact plug CTP3 may include a conductive material such as tungsten.

The fourth contact plug CTP4 may extend through the fourth stack 170S2 and be connected to the third contact plug CTP3. The third contact plug CTP3 and the fourth contact plug CTP4 may be directly electrically connected to each other without a bonding pad interposed therebetween. Here, a second plug connection portion CTPC2 where the third contact plug CTP3 and the fourth contact plug CTP4 are connected to each other may be disposed on the dielectric bonding structure 150. For example, the second plug connection portion CTPC2 may be disposed in the fourth interlayer insulating layer IL4. The fourth contact plug CTP4 may include a conductive material such as tungsten.

The fourth contact plug CTP4 may be electrically connected to the peripheral circuit PC through the third contact plug CTP3 and the peripheral circuit bonding structure 110. The third contact plug CTP3 and the fourth contact plug CTP4 may provide a path for transmitting a bias to the peripheral circuit PC. For example, the third contact plug CTP3 and the fourth contact plug CTP4 may provide a path for transmitting a bias applied to the third interconnection structure IC3 to the peripheral circuit PC.

The first contact vias CTV1 may extend through the first gate structure 120G. For example, the first contact vias CTV1 may extend through the first staircase structure SS1 of the first gate structure 120G and extend into the dielectric bonding structure 150. The first contact vias CTV1 may include protrusion portions, respectively, and may be respectively connected to the first conductive layers 120C through the protrusion portions. The first conductive layer 120C connected to the first contact via CTV1 may be the uppermost first conductive layer 120C of the first staircase structure SS1 among the first conductive layers 120C. Here, the uppermost first conductive layer 120C may refer to each of the first conductive layers 120C connected to the first contact vias CTV1 in the first staircase structure SS1 among the first conductive layers 120C rather than one first conductive layer 120C disposed at the uppermost portion of the first staircase structure SS1 among the first conductive layers 120C. The first contact vias CTV1 may extend through the first staircase structure SS1 and be electrically connected to the peripheral circuit PC. For example, the first contact vias CTV1 may be electrically connected to the peripheral circuit PC through the peripheral circuit bonding structure 110. The insulating spacers SP may be disposed between the first contact via CTV1 and the first conductive layers 120C. The first contact vias CTV1 may each include a conductive material such as tungsten. The insulating spacer SP may include an insulating material such as oxide.

The second contact vias CTV2 may extend through the second gate structure 170G. For example, the second contact vias CTV2 may extend through the second staircase structure SS2 of the second gate structure 170G and be connected to the first contact vias CTV1. The first contact vias CTV1 and the second contact vias CTV2 may be directly electrically connected to each other without bonding pads interposed therebetween. Here, a via connection portion CTVC where the first contact via CTV1 and the second contact via CTV2 are connected to each other may be disposed on the dielectric bonding structure 150. For example, the via connection portion CTVC may be disposed in the fourth interlayer insulating layer IL4.

The second contact vias CTV2 may include protrusion portions, respectively, and may be respectively connected to the second conductive layers 170C through the protrusion portions. The second conductive layer 170C connected to the second contact via CTV2 may be the uppermost second conductive layer 170C of the second staircase structure SS2 among the second conductive layers 170C. Here, the uppermost second conductive layer 170C may refer to each of the second conductive layers 170C connected to the second contact vias CTV2 in the second staircase structure SS2 among the second conductive layers 170C rather than one second conductive layer 170C disposed at the uppermost portion of the second staircase structure SS2 among the second conductive layers 170C. The insulating spacers SP may be disposed between the second contact via CTV2 and the second conductive layers 170C. The second contact vias CTV2 may each include a conductive material such as tungsten.

The second contact vias CTV2 may be electrically connected to the peripheral circuit PC. For example, the second contact vias CTV2 may be electrically connected to the peripheral circuit PC through the first contact vias CTV1 and the peripheral circuit bonding structure 110. Here, the second contact vias CTV2 may be connected to the row decoder.

The first contact vias CTV1 and the second contact vias CTV2 may provide paths for transmitting biases to word lines. For example, the first contact vias CTV1 and the second contact vias CTV2 may provide paths for transmitting biases to word lines connected to the memory string.

The third interconnection structure IC3 may be disposed on the second gate structure 170G, the second stack 170S1, or the fourth stack 170S2. The third interconnection structure IC3 may be disposed in the fifth interlayer insulating layer IL5. Here, the fifth interlayer insulating layer IL5 may be disposed on the second gate structure 170G. The third interconnection structure IC3 may include third vias ICE and third wiring lines ICF. The third interconnection structure IC3 may include a conductive material such as tungsten. The fifth interlayer insulating layer IL5 may include an insulating material such as oxide or nitride.

For reference, an embodiment in which the first gate structure 120G includes the first staircase structure SS1 and the second gate structure 170G includes the second staircase structure SS2 has been described in FIG. 1, but the first gate structure 120G and the second gate structure 170G might not include staircase structures. In such a case, the first contact vias CTV1 may extend into the first gate structure 120G and be respectively connected to the first conductive layers 120C, and the second contact vias CTV2 may extend into the second gate structure 170G and be respectively connected to the second conductive layers 170C. Here, the first contact vias CTV1 and the second contact vias CTV2 might not be connected to each other.

In addition, an embodiment in which the first contact vias CTV1 have substantially the same height and the second contact vias CTV2 have substantially the same height has been illustrated in FIG. 1, but heights of the first contact vias CTV1 may be different from each other or heights of the second contact vias CTV2 may be different from each other. In such a case, lower surfaces of the first contact vias CTV1 may be directly connected to the upper surfaces of the first conductive layers 120C exposed by the first staircase structures SS1, and lower surfaces of the second contact vias CTV2 may be directly connected to the upper surfaces of the second conductive layers 170C exposed by the second staircase structure SS2. Here, the first contact vias CTV1 and the second contact vias CTV2 might not be connected to each other.

According to the structure described above, the dielectric bonding structure 150 may extend between the first source structure 140 and the second source structure 160. Here, the dielectric bonding structure 150 may be used as a bonding structure.

In such a case, in order to electrically connect the first contact plug CTP1 and the second contact plug CTP2 to each other, the first contact plug CTP1 may extend through the dielectric bonding structure 150 and be connected to the second contact plug CTP2. Likewise, the third contact plug CTP3 may extend through the dielectric bonding structure 150 and be connected to the fourth contact plug CTP4. In addition, the first contact vias CTV1 may extend through the dielectric bonding structure 150 and be connected to the second contact vias CTV2.

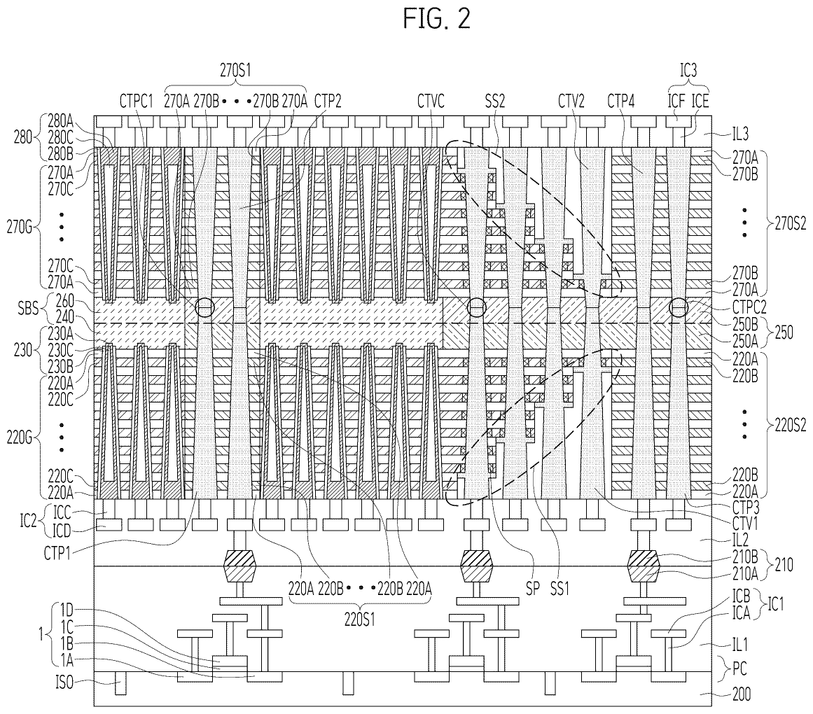

FIG. 2 is a diagram describing a semiconductor device in accordance with an embodiment of the present disclosure. Hereinafter, content overlapping with previously described content may be omitted.

Referring to the embodiment of FIG. 2, the semiconductor device may include a substrate 200, a peripheral circuit bonding structure 210, a first stack 220S1, a third stack 220S2, a first gate structure 220G, a first channel structure 230, a dielectric bonding structure 250, a source bonding structure SBS, a second stack 270S1, a fourth stack 270S2, a second gate structure 270G, a second channel structure 280, a first contact plug CTP1, a second contact plug CTP2, a third contact plug CTP3, a fourth contact plug CTP4, a first contact via CTV1, and a second contact via CTV2.

The semiconductor device may further include at least one of an element isolation layer ISO, a peripheral circuit PC, an insulating spacer SP, a first interconnection structure IC1, a second interconnection structure IC2, a third interconnection structure IC3, a first interlayer insulating layer IL1, a second interlayer insulating layer IL2, and a third interlayer insulating layer IL3.

The peripheral circuit PC may be disposed on the substrate 200. The peripheral circuit PC may include a transistor 1. For example, the peripheral circuit PC may include a page buffer and/or a row decoder. The transistor 1 may include junctions 1A and 1B, a gate electrode 1D, and a gate insulating layer 1C. The gate insulating layer 1C may be disposed between the gate electrode 1D and the substrate 200. The element isolation layer ISO may be disposed in the substrate 200, and an active region may be defined by the element isolation layer ISO. The transistor 1 may be disposed in the active region.

The first interconnection structure IC1 may be disposed on the substrate 200. The first interconnection structure IC1 may be disposed in the first interlayer insulating layer IL1. Here, the first interlayer insulating layer IL1 may be disposed on the substrate 200. The first interconnection structure IC1 may include first vias ICA and first wiring lines ICB. The first interconnection structure IC1 may be connected to the peripheral circuit PC.

The peripheral circuit bonding structure 210 may be disposed on the first interconnection structure IC1. The peripheral circuit bonding structure 210 may be electrically connected to the peripheral circuit PC through the first interconnection structure IC1. The peripheral circuit bonding structure 210 may include a first peripheral circuit bonding pad 210A and a second peripheral circuit bonding pad 210B. The first peripheral circuit bonding pad 210A may be disposed in the first interlayer insulating layer IL1. The second peripheral circuit bonding pad 210B may be disposed on the first peripheral circuit bonding pad 210A and disposed in the second interlayer insulating layer IL2. Here, the second interlayer insulating layer IL2 may be disposed on the first interlayer insulating layer IL1.

The second interconnection structure IC2 may be disposed on the peripheral circuit bonding structure 210. The second interconnection structure IC2 may be disposed in the second interlayer insulating layer IL2. The second interconnection structure IC2 may include second vias ICC and second wiring lines ICD. Some of the second wiring lines ICD may be used as bit lines. For example, second wiring lines ICD connected to the first channel structures 230 among the second wiring lines ICD may be used as the bit lines. The second interconnection structure IC2 may be connected to the peripheral circuit bonding structure 210.

The first gate structure 220G may be disposed over the peripheral circuit PC. The first gate structure 220G may include first insulating layers 220A and first conductive layers 220C that are alternately stacked. For example, the first conductive layers 220C may be gate lines. The first gate structure 220G may include a first staircase structure SS1. For example, the first gate structure 220G may include the first staircase structure SS1 exposing an upper surface of each of the first conductive layers 220C. The first staircase structure SS1 may have an inverted shape.

The first stack 220S1 and the third stack 22052 may be disposed at a level corresponding to the first gate structure 220G. The first stack 220S1 and the third stack 220S2 may each include first insulating layers 220A and first sacrificial layers 220B that are alternately stacked. The first stack 220S1 and the third stack 220S2 may be structures remaining without being replaced with the first gate structure 220G.

The second gate structure 270G may be disposed over the first gate structure 220G. The second gate structure 270G may include second insulating layers 270A and second conductive layers 270C that are alternately stacked. For example, the second conductive layers 270C may be gate lines. The second gate structure 270G may include a second staircase structure SS2. For example, the second gate structure 270G may include the second staircase structure SS2 exposing an upper surface of each of the second conductive layers 270C. The second staircase structure SS2 may have a shape which is symmetrical to the first staircase structure SS1.

The second stack 270S1 may be disposed over the first stack 220S1, and the fourth stack 270S2 may be disposed over the third stack 220S2. The second stack 270S1 and the fourth stack 270S2 may each include second insulating layers 270A and second sacrificial layers 270B that are alternately stacked. The second stack 270S1 and the fourth stack 270S2 may be structures remaining without being replaced with the second gate structure 270G.

The source bonding structure SBS may be disposed between the first gate structure 220G and the second gate structure 270G. The source bonding structure SBS may include a first source bonding pattern 240 and a second source bonding pattern 260 disposed on the first source bonding pattern 240. In a process of manufacturing the semiconductor device, the first source bonding pattern 240 and the second source bonding pattern 260 may be directly bonded to each other.

Comparing FIG. 2 with FIG. 1, the first source structure 140 and the second source structure 160 of FIG. 1 are not used as bonding structures, whereas the first source bonding pattern 240 and the second source bonding pattern 260 of FIG. 2 may be used as bonding structures. Here, the source bonding structure SBS may include a conductive material such as polysilicon.

The dielectric bonding structure 250 may be disposed at a level corresponding to the source bonding structure SBS. The dielectric bonding structure 250 and source bonding structure SBS may be disposed at a same level. The dielectric bonding structure 250 may include a first dielectric bonding pattern 250A and a second dielectric bonding pattern 250B disposed on the first dielectric bonding pattern 250A. Here, the first dielectric bonding pattern 250A may be disposed at a level corresponding to the first source bonding pattern 240, and the second dielectric bonding pattern 250B may be disposed at a level corresponding to the second source bonding pattern 260. Here, the dielectric bonding structure 250 may include a dielectric material.

The dielectric bonding structure 250 may be used as a bonding structure. For example, in the process of manufacturing the semiconductor device, the first dielectric bonding pattern 250A and the second dielectric bonding pattern 250B may be directly bonded to each other. According to an embodiment of the present disclosure, the first source bonding pattern 240 and the second source bonding pattern 260 may be used as bonding structures and the first dielectric bonding pattern 250A and the second dielectric bonding pattern 250B may be used as bonding structures, without forming separate bonding pads.

The first channel structures 230 may extend into the source bonding structure SBS through the first gate structure 220G. For example, the first channel structures 230 may extend into the first source bonding pattern 240 through the first gate structure 220G. Each of the first channel structures 230 may include at least one of a first channel layer 230A, a first memory layer 230B surrounding the first channel layer 230A, and a first insulating core 230C disposed in the first channel layer 230A. Here, the first channel layers 230A of the first channel structures 230 may be connected to the first source bonding pattern 240.

The second channel structures 280 may extend into the source bonding structure SBS through the second gate structure 270G. For example, the second channel structures 280 may extend into the second source bonding pattern 260 through the second gate structure 270G. Each of the second channel structures 280 may include at least one of a second channel layer 280A, a second memory layer 280B surrounding the second channel layer 280A, and a second insulating core 280C disposed in the second channel layer 280A. Here, the second channel layers 280A of the second channel structures 280 may be connected to the second source bonding pattern 260.

The first channel structures 230 and the second channel structures 280 may share the source bonding structure SBS with each other. For example, the first channel structures 230 and the second channel structures 280 may share one source bonding structure SBS with each other.

The first contact plug CTP1 may extend through the first stack 220S1 and extend into the dielectric bonding structure 250. The first contact plug CTP1 may be electrically connected to the peripheral circuit PC. For example, the first contact plug CTP1 may be electrically connected to the peripheral circuit PC through the peripheral circuit bonding structure 210.

The second contact plug CTP2 may extend through the second stack 270S1. For example, the second contact plug CTP2 may extend through the second stack 270S1 and be connected to the first contact plug CTP1. The first contact plug CTP1 and the second contact plug CTP2 may be directly electrically connected to each other without a bonding pad interposed therebetween. A first plug connection portion CTPC1 where the first contact plug CTP1 and the second contact plug CTP2 are connected to each other may be disposed in the dielectric bonding structure 250.

The second contact plug CTP2 may be electrically connected to the peripheral circuit PC. For example, the second contact plug CTP2 may be electrically connected to the peripheral circuit PC through the first contact plug CTP1 and the peripheral circuit bonding structure 210. Here, the second contact plug CTP2 may be connected to the page buffer.

The first contact plug CTP1 and the second contact plug CTP2 may provide a path for transmitting a bias to the bit line. For example, the first contact plug CTP1 and the second contact plug CTP2 may provide a path for transmitting a bias to a bit line connected to a memory string.

The third contact plug CTP3 may extend through the third stack 220S2 and extend into the dielectric bonding structure 250. The third contact plug CTP3 may be electrically connected to the peripheral circuit PC. For example, the third contact plug CTP3 may be electrically connected to the peripheral circuit PC through the peripheral circuit bonding structure 210.

The fourth contact plug CTP4 may extend through the fourth stack 270S2 and be connected to the third contact plug CTP3. The third contact plug CTP3 and the fourth contact plug CTP4 may be directly electrically connected to each other without a bonding pad interposed therebetween. A second plug connection portion CTPC2 where the third contact plug CTP3 and the fourth contact plug CTP4 are connected to each other may be disposed in the dielectric bonding structure 250.

The fourth contact plug CTP4 may be electrically connected to the peripheral circuit PC through the third contact plug CTP3 and the peripheral circuit bonding structure 210. The third contact plug CTP3 and the fourth contact plug CTP4 may provide a path for transmitting a bias to the peripheral circuit PC. For example, the third contact plug CTP3 and the fourth contact plug CTP4 may provide a path for transmitting a bias applied to the third interconnection structure IC3 to the peripheral circuit PC.

The first contact vias CTV1 may extend through the first gate structure 220G and extend into the dielectric bonding structure 250. The first contact vias CTV1 may be connected to the first conductive layers 220C through protrusion portions.

The first contact vias CTV1 may extend through the first staircase structure SS1 and be electrically connected to the peripheral circuit PC. For example, the first contact vias CTV1 may be electrically connected to the peripheral circuit PC through the peripheral circuit bonding structure 210. The insulating spacers SP may be disposed between the first contact via CTV1 and the first conductive layers 220C.

The second contact vias CTV2 may extend through the second gate structure 270G. For example, the second contact vias CTV2 may extend through the second staircase structure SS2 of the second gate structure 270G and be connected to the first contact vias CTV1. The first contact vias CTV1 and the second contact vias CTV2 may be directly electrically connected to each other without bonding pads interposed therebetween. A via connection portion CTVC where the first contact via CTV1 and the second contact via CTV2 are connected to each other may be disposed in the dielectric bonding structure 250. The second contact vias CTV2 may be connected to the second conductive layers 270C through protrusion portions. The insulating spacers SP may be disposed between the second contact via CTV2 and the second conductive layers 270C.

The second contact vias CTV2 may be electrically connected to the peripheral circuit PC. For example, the second contact vias CTV2 may be electrically connected to the peripheral circuit PC through the first contact vias CTV1 and the peripheral circuit bonding structure 210. Here, the second contact vias CTV2 may be connected to the row decoder.

The first contact vias CTV1 and the second contact vias CTV2 may provide paths for transmitting biases to word lines. For example, the first contact vias CTV1 and the second contact vias CTV2 may provide paths for transmitting biases to word lines connected to the memory string.

The third interconnection structure IC3 may be disposed on the second gate structure 270G, the second stack 270S1, or the fourth stack 270S2. The third interconnection structure IC3 may be disposed in the third interlayer insulating layer IL3. Here, the third interlayer insulating layer IL3 may be disposed on the second gate structure 270G. The third interconnection structure IC3 may include third vias ICE and third wiring lines ICF.

According to the structure described above, the dielectric bonding structure 250 and the source bonding structure SBS may be used as the bonding structures. For example, in the process of manufacturing the semiconductor device, the first source bonding pattern 240 and the second source bonding pattern 260 may be used as the bonding structures and the first dielectric bonding pattern 250A and the second dielectric bonding pattern 250B may be used as the bonding structures, without forming the separate bonding pads. Here, the source bonding structure SBS may be used as both a source structure connected to the first channel structures 230 and the second channel structures 280 and the bonding structure.

In such a case, in order to electrically connect the first contact plug CTP1 and the second contact plug CTP2 to each other, the first contact plug CTP1 may extend through the dielectric bonding structure 250 and be connected to the second contact plug CTP2. Likewise, the third contact plug CTP3 may extend through the dielectric bonding structure 250 and be connected to the fourth contact plug CTP4. In addition, the first contact vias CTV1 may extend through the dielectric bonding structure 250 and be connected to the second contact vias CTV2.

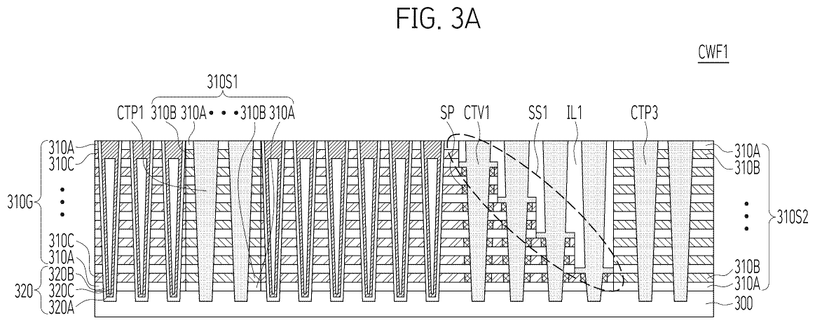

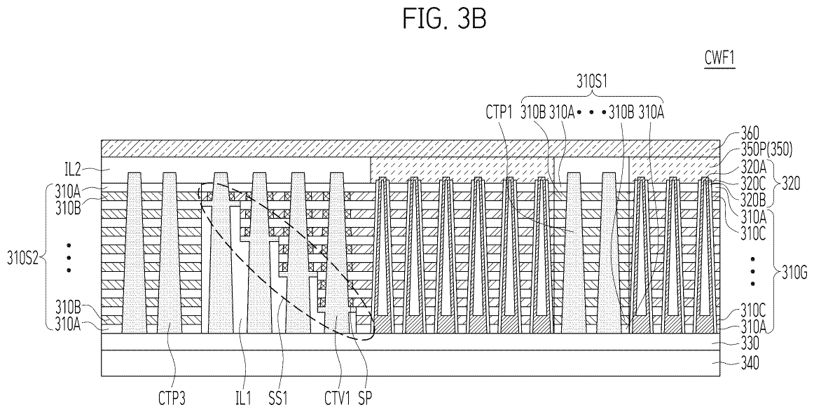

FIGS. 3A and 3B, FIG. 4, FIGS. 5A to 5C, and FIGS. 6 and 7 are diagrams describing a manufacturing method of a semiconductor device in accordance with an embodiment of the present disclosure. Hereinafter, content overlapping with previously described content may be omitted.

Referring to FIG. 3A, a first cell wafer CWF1 may be formed. First, a first stack 310S1 may be formed on a first substrate 300. For example, the first stack 310S1 may be formed by alternately stacking first material layers 310A and second material layers 310B. Here, the first stack 310S1 may include a first staircase structure SS1 exposing upper surfaces of the second material layers 310B. A first interlayer insulating layer IL1 may be formed on the first staircase structure SS1. The first material layers 310A may each include an insulating material such as oxide, and the second material layers 310B may each include a sacrificial material such as nitride.

The first stack 310S1 may include a cell region, a first contact region, and a second contact region. The cell region may be a region where memory cells are to be stacked, the first contact region may be a region where first contact plugs connected to a page buffer of a peripheral circuit are to be formed, and the second contact region may be a region where third contact plugs for transmitting biases to the peripheral circuit are to be formed.

Subsequently, first channel structures 320 extending through the cell region of the first stack 310S1 may be formed. Here, each of the first channel structures 320 may include a first channel layer 320A, a first memory layer 320B surrounding the first channel layer 320A, and a first insulating core 320C disposed in the first channel layer 320A.

First contact plugs CTP1 extending through the first contact region of the first stack 310S1 may be formed. Third contact plugs CTP3 extending through the second contact region of the first stack 310S1 may be formed. Here, the first contact plugs CTP1 and the third contact plugs CTP3 may each include a conductive material such as tungsten.

First contact vias CTV1 extending through the first stack 310S1 may be formed. For example, the first contact vias CTV1 extending through the first staircase structure SS1 may be formed. The first contact vias CTV1 may include protrusion portions, and may be connected to the second material layers 310B through the protrusion portions. The first contact vias CTV1 may each include a conductive material such as tungsten.

Subsequently, the second material layers 310B may be replaced with fifth material layers 310C through a first slit (not illustrated). Consequently, a first gate structure 310G in which the first material layers 310A and the fifth material layers 310C are alternately stacked may be defined. Accordingly, the first gate structure 310G may be disposed at a level corresponding to the first stack 310S1. Insulating spacers SP may be formed between the first gate structure 310G and the first contact vias CTV1.

In partial regions of the first stack 310S1, the second material layers 310B might not be replaced with the fifth material layers 310C. For example, in the first contact region and the second contact region of the first stack 310S1, the second material layers 310B may remain without being replaced with the fifth material layers 310C. Here, the first contact region where the second material layers 310B remain may be defined as the first stack 310S1, and the second contact region where the second material layers 310B remain may be defined as a third stack 310S2. Here, the fifth material layers 310C may each include a conductive material such as tungsten, molybdenum, or polysilicon.

For reference, when the second material layers 310B each include a conductive material, a process of replacing the second material layers 310B with the fifth material layers 310C may be omitted. In such a case, the first stack 310S1 may be used as the first gate structure 310G.

The first contact vias CTV1 may include protrusion portions, respectively, and may be respectively connected to the fifth material layers 310C through the protrusion portions. The fifth material layer 310C connected to the first contact via CTV1 may be the uppermost fifth material layer 310C of the first staircase structure SS1 among the fifth material layers 310C. Here, the uppermost fifth material layer 310C may refer to each of the fifth material layers 310C connected to the first contact vias CTV1 in the first staircase structure SS1 among the fifth material layers 310C rather than one fifth material layer 310C disposed at the uppermost portion of the first staircase structure SS1 among the fifth material layers 310C.

Referring to FIG. 3B, the first cell wafer CWF1 may be rotated. First, a dummy bonding layer 330 may be formed on the first cell wafer CWF1. Subsequently, the dummy bonding layer 330 and a dummy substrate 340 may be bonded to each other. In such a case, the first cell wafer CWF1 may be rotated so that a lower surface of the first substrate 300 is exposed.

Subsequently, a first source structure 350P may be formed over the first gate structure 310G. First, in a state where the first cell wafer CWF1 is rotated, the first substrate 300 may be removed. Subsequently, portions of the first memory layers 320B may be removed so that the first channel layers 320A of the first channel structures 320 are exposed. Subsequently, a preliminary source layer 350 may be formed over the first gate structure 310G. Here, the preliminary source layer 350 may include a conductive material such as polysilicon. Subsequently, the preliminary source layer 350 may be annealed. Subsequently, the first source structure 350P may be formed by patterning the preliminary source layer 350 so that the preliminary source layer 350 remains in a region corresponding to the first channel structures 320. Here, the first channel layers 320A of the first channel structures 320 may be connected to the first source structure 350P.

Subsequently, a second interlayer insulating layer IL2 may be formed in a region where the preliminary source layer 350 is removed. Subsequently, a first dielectric bonding layer 360 may be formed on the first source structure 350P. Here, the first dielectric bonding layer 360 may include a dielectric material.

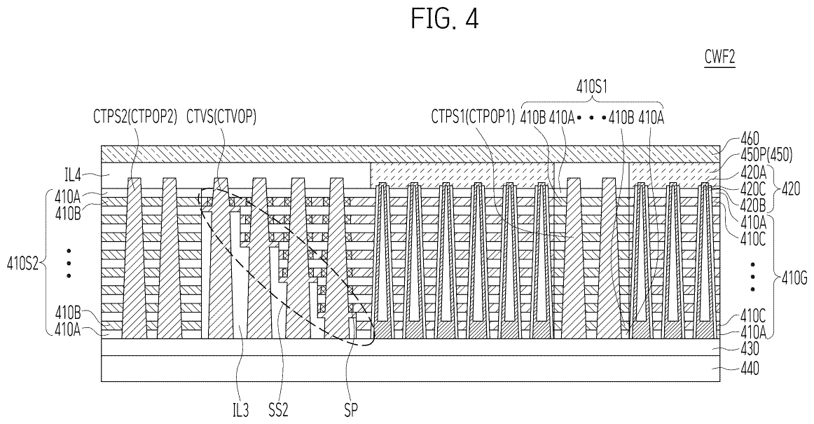

Referring to FIG. 4, a second cell wafer CWF2 may be formed. First, a second stack 410S1 may be formed by alternately stacking third material layers 410A and fourth material layers 410B over a second substrate (not illustrated). Here, the second stack 410S1 may include a second staircase structure SS2 exposing upper surfaces of the fourth material layers 410B. A third interlayer insulating layer IL3 may be formed on the second staircase structure SS2. The third material layers 410A may each include an insulating material such as oxide, and the fourth material layers 410B may each include a sacrificial material such as nitride.

The second stack 410S1 may include a cell region, a first contact region, and a second contact region. The cell region may be a region where memory cells are to be stacked, the first contact region may be a region where second contact plugs connected to the page buffer of the peripheral circuit are to be formed, and the second contact region may be a region where fourth contact plugs for transmitting biases to the peripheral circuit are to be formed.

Subsequently, second channel structures 420 extending through the cell region of the second stack 410S1 may be formed. Each of the second channel structures 420 may include a second channel layer 420A, a second memory layer 420B surrounding the second channel layer 420A, and a second insulating core 420C disposed in the second channel layer 420A.

First contact openings CTPOP1 extending through the first contact region of the second stack 410S1 may be formed. Second contact openings CTPOP2 extending through the second contact region of the second stack 410S1 may also be formed. Via openings CTVOP extending through the second stack 410S1 may be formed. When the first contact openings CTPOP1 are formed, the second contact openings CTPOP2 and the via openings CTVOP may be formed. The first contact openings CTPOP1, the second contact openings CTPOP2, and the via openings CTVOP may be formed at the same time.

Subsequently, first contact sacrificial layers CTPS1 may be formed in the first contact openings CTPOP1. Second contact sacrificial layers CTPS2 may be formed in the second contact openings CTPOP2. Via sacrificial layers CTVS may be formed in the via openings CTVOP. When the first contact sacrificial layers CTPS1 are formed, the second contact sacrificial layers CTPS2 and the via sacrificial layers CTVS may be formed. Here, the first contact sacrificial layers CTPS1, the second contact sacrificial layers CTPS2, and the via sacrificial layers CTVS may each include a sacrificial material such as tungsten or polysilicon.

Subsequently, the fourth material layers 410B may be replaced with sixth material layers 410C through a second slit (not illustrated). Consequently, a second gate structure 410G in which the third material layers 410A and the sixth material layers 410C are alternately stacked may be defined. Accordingly, the second gate structure 410G may be disposed at a level corresponding to the second stack 410S1. Insulating spacers SP may be formed between the second gate structure 410G and the vias sacrificial layers CTVS.

The vias sacrificial layers CTVS may include protrusion portions, respectively, and may be respectively connected to the sixth material layers 410C through the protrusion portions. The sixth material layer 410C connected to the via sacrificial layers CTVS may be the uppermost sixth material layer 410C of the sixth material layers 410C. Here, the uppermost sixth material layer 410C may refer to each of the sixth material layers 410C connected to the via sacrificial layers CTVS in the second staircase structure SS2 among the sixth material layers 410C rather than one sixth material layer 410C disposed at the uppermost portion of the second staircase structure SS2 among the sixth material layers 410C.

In partial regions of the second stack 410S1, the fourth material layers 410B might not be replaced with the sixth material layers 410C. For example, in the first contact region and the second contact region of the second stack 410S1, the fourth material layers 410B may remain without being replaced with the sixth material layers 410C. Here, the first contact region where the fourth material layers 410B remain may be defined as the second stack 410S1, and the second contact region where the fourth material layers 410B remain may be defined as a fourth stack 410S2. Here, the sixth material layers 410C may each include a conductive material such as tungsten, molybdenum, or polysilicon.

Subsequently, the second cell wafer CWF2 may be rotated. First, a dummy bonding layer 430 may be formed on the second cell wafer CWF2. Subsequently, the dummy bonding layer 430 and a dummy substrate 440 may be bonded to each other. In such a case, the second cell wafer CWF2 may be rotated so that a lower surface of the second substrate is exposed.

Subsequently, a second source structure 450P may be formed on the second gate structure 410G. Subsequently, a fourth interlayer insulating layer IL4 may be formed on the second gate structure 410G. Subsequently, a second dielectric bonding layer 460 may be formed on the second gate structure 410G. For example, the second source structure 450P, the fourth interlayer insulating layer IL4 and the second dielectric bonding layer 460 may be formed using a method of forming the first source structure 350P, the second interlayer insulating layer IL2, and the first dielectric bonding layer 360 of the first cell wafer CWF1 of FIG. 3B.

Referring to FIG. 5A, the first cell wafer CWF1 and the second cell wafer CWF2 may be bonded to each other. For example, the first dielectric bonding layer 360 of the first cell wafer CWF1 and the second dielectric bonding layer 460 of the second cell wafer CWF2 may be directly bonded to each other.

Referring to FIG. 5B, the first contact openings CTPOP1 may be reopened by removing the first contact sacrificial layers CTPS1. The second contact openings CTPOP2 may be reopened by removing the second contact sacrificial layers CTPS2. The via openings CTVOP may be reopened by removing the via sacrificial layers CTVS. When the first contact sacrificial layers CTPS1 are removed, the second contact sacrificial layers CTPS2 and the via sacrificial layers CTVS may be removed.

Subsequently, the first contact plugs CTP1 may be exposed by expanding the first contact openings CTPOP1. The third contact plugs CTP2 may be exposed by expanding the second contact openings CTPOP2. The first contact vias CTV1 may be exposed by expanding the via openings CTVOP. When the first contact openings CTPOP1 are expanded, the second contact openings CTPOP2 and the via openings CTVOP may be expanded.

Subsequently, second contact plugs CTP2 may be formed in the first contact openings CTPOP1. For example, the second contact plugs CTP2 connected to the first contact plugs CTP1 may be formed. Fourth contact plugs CTP4 connected to the third contact plugs CTP3 may be formed in the second contact openings CTPOP2. Second contact vias CTV2 connected to the first contact vias CTV1 may be formed in the via openings CTVOP.

According to an embodiment of the present disclosure, separate bonding pads might not be formed in order to bond the first cell wafer CWF1 and the second cell wafer CWF2 to each other. In such a case, in order to electrically connect the first cell wafer CWF1 and the second cell wafer CWF2 to each other, the first contact plugs CTP1, the third contact plugs CTP3, and the first contact vias CTV1 of the first cell wafer CWF1 may be exposed by expanding the first contact openings CTPOP1, the second contact openings CTPOP2, and the via openings CTVOP of the second cell wafer CWF2. The second contact plugs CTP2, the fourth contact plugs CTP4, and the second contact vias CTV2 may be directly connected to the first contact plugs CTP1, the third contact plugs CTP3, and the first contact vias CTV1, respectively, by forming the second contact plugs CTP2, the fourth contact plugs CTP4, and the second contact vias CTV2 in the first contact openings CTPOP1, the second contact openings CTPOP2, and the via openings CTVOP, respectively.

Referring to FIG. 5C, a first interconnection structure IC1 may be formed by first removing the dummy substrate 440 and the dummy bonding layer 430. Subsequently, the first interconnection structure IC1 may be formed on the second gate structure 410G. The first interconnection structure IC1 may be formed in a fifth interlayer insulating layer IL5. The fifth interlayer insulating layer IL5 may be formed on the second gate structure 410G. The first interconnection structure IC1 may include first vias ICA and first wiring lines ICB. At least one of the first vias ICA may be connected to at least one of the second channel structures 420, the second contact plugs CTP2, the fourth contact plugs CTP4, and the second contact vias CTV2. The first wiring lines ICB may connect the first vias ICA to each other.

Subsequently, first peripheral circuit bonding pads 510 may be formed on the first interconnection structure IC1. At least one of the first peripheral circuit bonding pads 510 may be electrically connected to at least one of the second contact plugs CTP2, the fourth contact plugs CTP4, and the second contact vias CTV2. The first peripheral circuit bonding pads 510 may each include a conductive material such as copper.

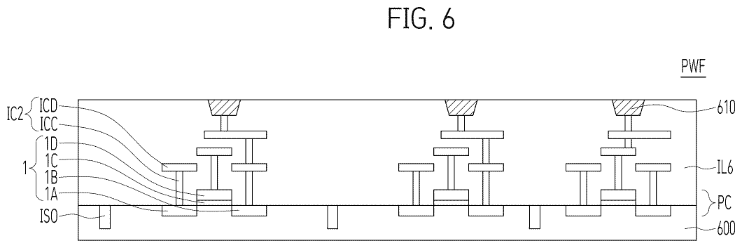

Referring to FIG. 6, a peripheral circuit wafer PWF may be formed. First, a peripheral circuit PC may be formed on a third substrate 600. The peripheral circuit PC may include a transistor 1. For example, the peripheral circuit PC may include a page buffer and/or a row decoder. The transistor 1 may include junctions 1A and 1B, a gate electrode 1D, and a gate insulating layer 1C. Here, the gate insulating layer 1C may be disposed between the gate electrode 1D and the third substrate 600. An element isolation layer ISO may be disposed in the third substrate 600, and an active region may be defined by the element isolation layer ISO. The transistor 1 may be disposed in the active region.

Subsequently, a second interconnection structure IC2 may be formed on the peripheral circuit PC. The second interconnection structure IC2 may be formed in a sixth interlayer insulating layer IL6. Here, the sixth interlayer insulating layer IL6 may be formed on the third substrate 600. The second interconnection structure IC2 may include second vias ICC and second wiring lines ICD. At least one of the second vias ICC may be connected to the peripheral circuit PC. The second wiring lines ICD may connect the second vias ICC to each other.

Second peripheral circuit bonding pads 610 may be formed on the second interconnection structure IC2. For example, the second peripheral circuit bonding pads 610 electrically connected to the peripheral circuit PC through the second interconnection structure IC2 may be formed. Each of the second peripheral circuit bonding pads 610 may include a conductive material such as copper.

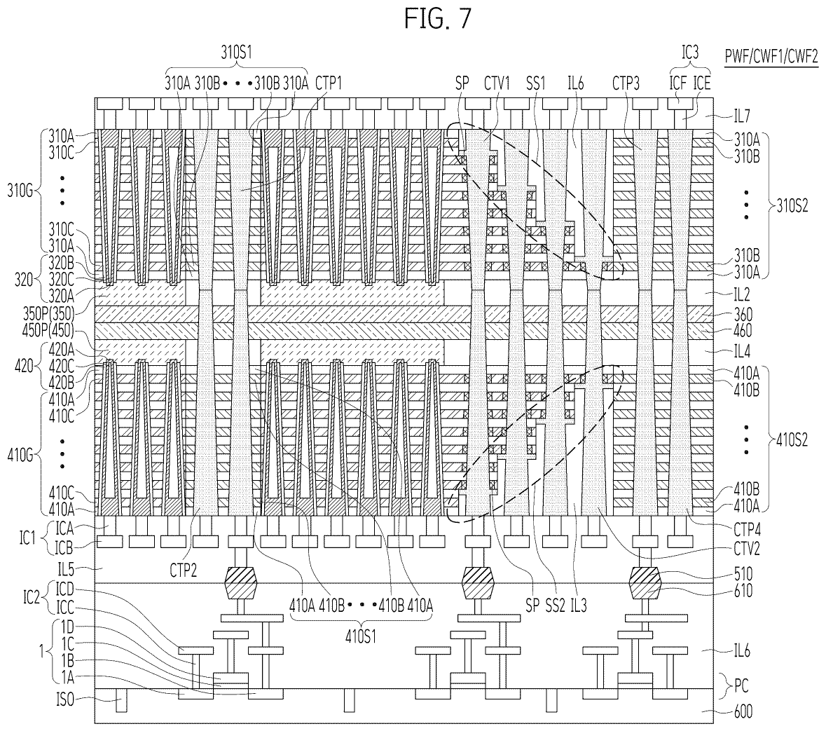

Referring to FIG. 7, the second cell wafer CWF2 and the peripheral circuit wafer PWF may be bonded to each other. For example, the first peripheral circuit bonding pads 510 of the second cell wafer CWF2 and the second peripheral circuit bonding pads 610 of the peripheral circuit wafer PWF may be directly bonded to each other.

In such a case, the first contact plugs CTP1, the third contact plugs CTP3, and the first contact vias CTV1 of the first cell wafer CWF1 may be electrically connected to the peripheral circuit PC through the second contact plug CTP2, the fourth contact plugs CTP4, the second contact vias CTV2, and the first peripheral circuit bonding pad 510 of the second cell wafer CWF2 and the second peripheral circuit bonding pads 610 of the peripheral circuit wafer PWF.

Here, the first contact plugs CTP1 may be connected to the page buffer. The first contact plugs CTP1 and the second contact plugs CTP2 may provide paths for transmitting biases to bit lines. For example, the first contact plug CTP1 and the second contact plug CTP2 may provide a path for transmitting a bias to a bit line connected to a memory string.

The third contact plugs CTP3 and the fourth contact plugs CTP4 may provide paths for transmitting biases to the peripheral circuit PC. For example, the third contact plug CTP3 and the fourth contact plug CTP4 may provide a path for transmitting a bias applied to a third interconnection structure IC3 to the peripheral circuit PC.

The first contact vias CTV1 may be connected to the row decoder. The first contact vias CTV1 and the second contact vias CTV2 may provide paths for transmitting biases to word lines. For example, the first contact vias CTV1 and the second contact vias CTV2 may provide paths for transmitting biases to word lines connected to the memory string.

Subsequently, the third interconnection structure IC3 may be formed. The third interconnection structure IC3 may be formed on the first cell wafer CWF1, and may include third vias ICE and third wiring lines ICF. The third interconnection structure IC3 may be disposed in a seventh interlayer insulating layer IL7. The seventh interlayer insulating layer IL7 may be formed on the first cell wafer CWF1.

According to the manufacturing method described above, after the first and second cell wafers CWF1 and CWF2 are bonded to each other, the first peripheral circuit bonding pads 510 and the second peripheral circuit bonding pads 610 may be formed. After the first source structure 350P of the first cell wafer CWF1 and the second source structure 450P of the second cell wafer CWF2 are formed, the first peripheral circuit bonding pads 510 and the second peripheral circuit bonding pads 610 may be formed. In such a case, the first source structure 350P and the second source structure 450P may be formed without being restricted by the first peripheral circuit bonding pads 510 and the second peripheral circuit bonding pads 610 each including copper or the like which are vulnerable to heat.

In addition, the first dielectric bonding layer 360 of the first cell wafer CWF1 and the second dielectric bonding layer 460 of the second cell wafer CWF2 may be bonded to each other. In such a case, in order to electrically connect the first cell wafer CWF1 and the second cell wafer CWF2 to each other, after the first contact openings CTPOP1, the second contact openings CTPOP2, and the via openings CTVOP of the second cell wafer CWF2 are expanded, the second contact plugs CTP2, the fourth contact plugs CTP4, and the second contact vias CTV2 directly connected to the first contact plugs CTP1, the third contact plugs CTP3, and the first contact vias CTV1 of the first cell wafer CWF1, respectively, may be formed in the first contact openings CTPOP1, the second contact openings CTPOP2, and the via openings CTVOP, respectively.

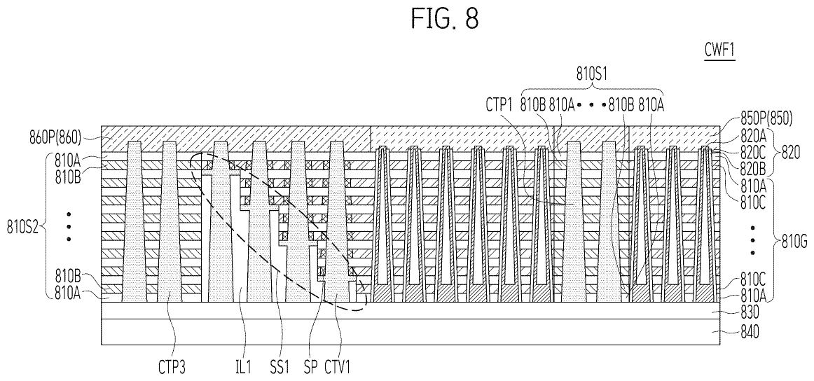

FIGS. 8 to 11 are diagrams describing a manufacturing method of a semiconductor device in accordance with an embodiment of the present disclosure. Hereinafter, content overlapping with previously described content may be omitted.

Referring to FIG. 8, a first cell wafer CWF1 may be formed, for example, by using the method of forming the first cell wafer CWF1 of FIGS. 3A and 3B. For example, the first cell wafer CWF1 including a first stack 810S1, a third stack 810S2, a first gate structure 810G, first channel structures 820, first contact plugs CTP1, third contact plugs CTP3, and first contact vias CTV1 may be formed.

Here, the first stack 810S1 may include first material layers 810A and second material layers 810B that are alternately stacked. The first gate structure 810G may include first material layers 810A and fifth material layers 810C that are alternately stacked. The first gate structure 810G may include a first staircase structure SS1.

The first channel structures 820 may extend through the first gate structure 810G. Each first channel structure 820 may include at least one of a first channel layer 820A, a first memory layer 820B surrounding the first channel layer 820A, and a first insulating core 820C disposed in the first channel layer 820A. The first contact plug CTP1 may extend through the first stack 810S1. The third contact plug CTP3 may extend through the third stack 810S2. The first contact vias CTV1 may extend through the first gate structure 810G. For example, the first contact vias CTV1 may extend through the first staircase structure SS1 and be connected to the fifth material layers 810C. Insulating spacers SP may be formed between the first contact vias CTV1 and the first gate structure 810G.

Subsequently, the first cell wafer CWF1 may be rotated. First, a dummy bonding layer 830 may be formed on the first cell wafer CWF1. Subsequently, the dummy bonding layer 830 and a dummy substrate 840 may be bonded to each other. In such a case, the first cell wafer CWF1 may be rotated.

Subsequently, a first source bonding pattern 850P may be formed on the first gate structure 810G. First, in a state where the first cell wafer CWF1 is rotated, portions of the first memory layers 820B may be removed so that the first channel layers 820A of the first channel structures 820 are exposed. Subsequently, a first source bonding layer 850 may be formed on the first gate structure 810G. Here, the first source bonding layer 850 may include a conductive material such as polysilicon. Subsequently, the first source bonding layer 850 may be annealed. Subsequently, the first source bonding pattern 850P may be formed by patterning the first source bonding layer 850 so that the first source bonding layer 850 remains in a region corresponding to the first channel structures 420. Here, the first channel layers 820A of the first channel structures 820 may be connected to the first source bonding pattern 850P.

Subsequently, a first dielectric bonding pattern 860P may be formed in a region where the first source bonding layer 850 is removed. First, a first dielectric bonding layer 860 may be formed on the first gate structure 810G. Here, the first dielectric bonding layer 860 may include a dielectric material. Subsequently, the first dielectric bonding pattern 860P may be formed by patterning the first dielectric bonding layer 860 so that the first dielectric bonding layer 860 remains in the region where the first source bonding layer 850 is removed.

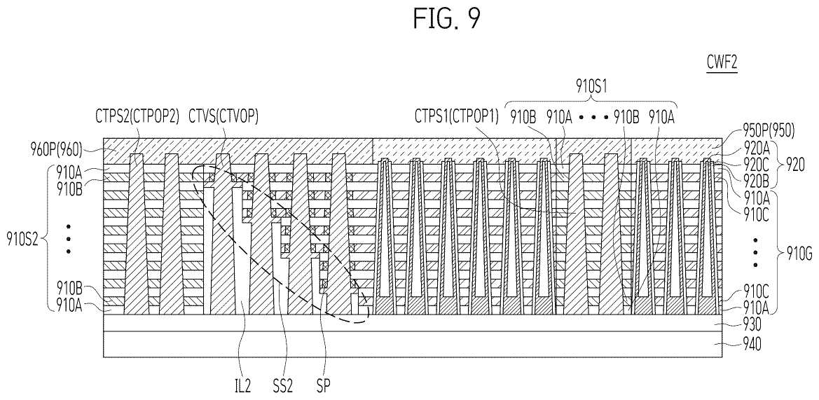

Referring to FIG. 9, a second cell wafer CWF2 may be formed, for example, by using the method of forming the second cell wafer CWF2 of FIG. 4. For example, the second cell wafer CWF2 including a second stack 910S1, a fourth stack 910S2, a second gate structure 910G, second channel structures 920, first contact sacrificial layers CTPS1, second contact sacrificial layers CTPS2, and via sacrificial layers CTVS may be formed.

Here, the second stack 910S1 may include third material layers 910A and fourth material layers 910B that are alternately stacked. The second gate structure 910G may include third material layers 910A and sixth material layers 910C that are alternately stacked. The second gate structure 910G may include a second staircase structure SS2. The second channel structures 920 may extend through the second gate structure 910G, and may each include at least one of a second channel layer 920A, a second memory layer 920B, and a second insulating core 920C. The first contact sacrificial layers CTPS1 may extend through the second stack 910S2. The second contact sacrificial layers CTPS2 may extend through the fourth stack 910S2. The via sacrificial layers CTVS may extend through the second gate structure 910G. For example, the via sacrificial layers CTVS may extend through the second staircase structure SS2 of the second gate structure 910G.

Subsequently, a second source bonding pattern 950P and a second dielectric bonding pattern 960P may be formed on the second gate structure 910G. For example, the second source bonding pattern 950P and the second dielectric bonding pattern 960P may be formed on the second gate structure 910G using a method of forming the first source bonding pattern 850P and the first dielectric bonding pattern 860P of FIG. 8.

For example, the second cell wafer CWF2 may be rotated using a dummy bonding layer 930 and a dummy substrate 940. Subsequently, the second source bonding patterns 950P may be formed by forming a second source bonding layer 950 on the second gate structure 910G and then patterning the second source bonding layer 950. The second dielectric bonding patterns 960P may be formed by forming a second dielectric bonding layer 960 on the second gate structure 910G and then patterning the second dielectric bonding layer 960.

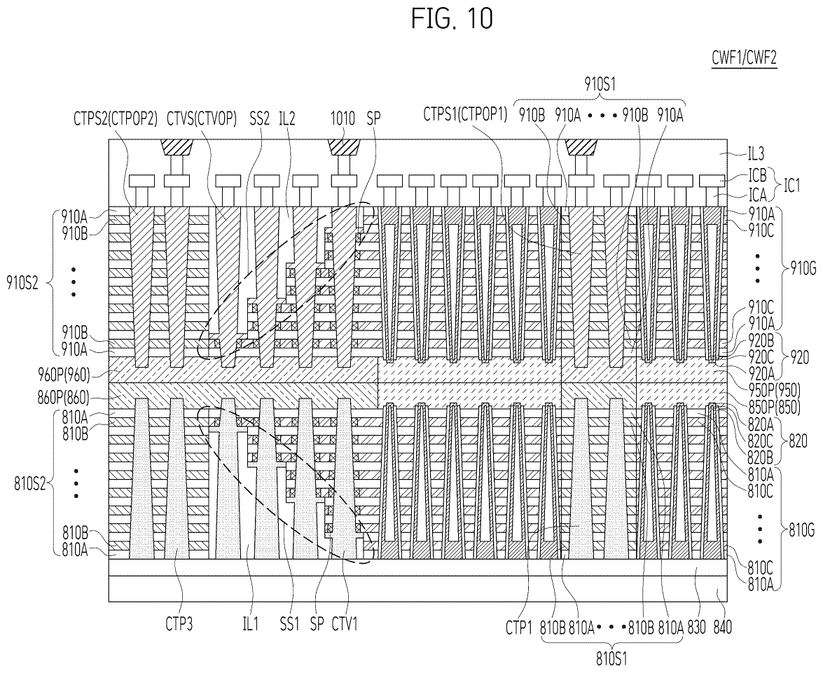

Referring to FIG. 10, the first cell wafer CWF1 and the second cell wafer CWF2 may be bonded to each other. For example, the first source bonding pattern 850P of the first cell wafer CWF1 and the second source bonding pattern 950P of the second cell wafer CWF2 may be directly bonded to each other. Also, the first dielectric bonding pattern 860P of the first cell wafer CWF1 and the second dielectric bonding pattern 960P of the second cell wafer CWF2 may be directly bonded to each other.

According to an embodiment of the present disclosure, the first dielectric bonding pattern 860P and the second dielectric bonding pattern 960P may be directly bonded to each other, and the first source bonding pattern 850P and the second source bonding pattern 950P may be directly bonded to each other. Accordingly, not only the first dielectric bonding pattern 860P and the second dielectric bonding pattern 960P, but also the first source bonding pattern 850P and the second source bonding pattern 950P may be used as bonding structures.

In addition, the first channel structures 820 of the first cell wafer CWF1 and the second channel structures 920 of the second cell wafer CWF2 may share the first source bonding pattern 850P and the second source bonding pattern 950P as source structures with each other. The first source bonding pattern 850P and the second source bonding pattern 950P may be used as the bonding structures and used as the source structures.

Subsequently, a first interconnection structure IC1 may be formed in a third interlayer insulating layer IL3, and may include first vias ICA and first wiring lines ICB. Subsequently, first peripheral circuit bonding pads 1010 may be formed on the first interconnection structure IC1. The first peripheral circuit bonding pads 1010 may each include a conductive material such as copper.

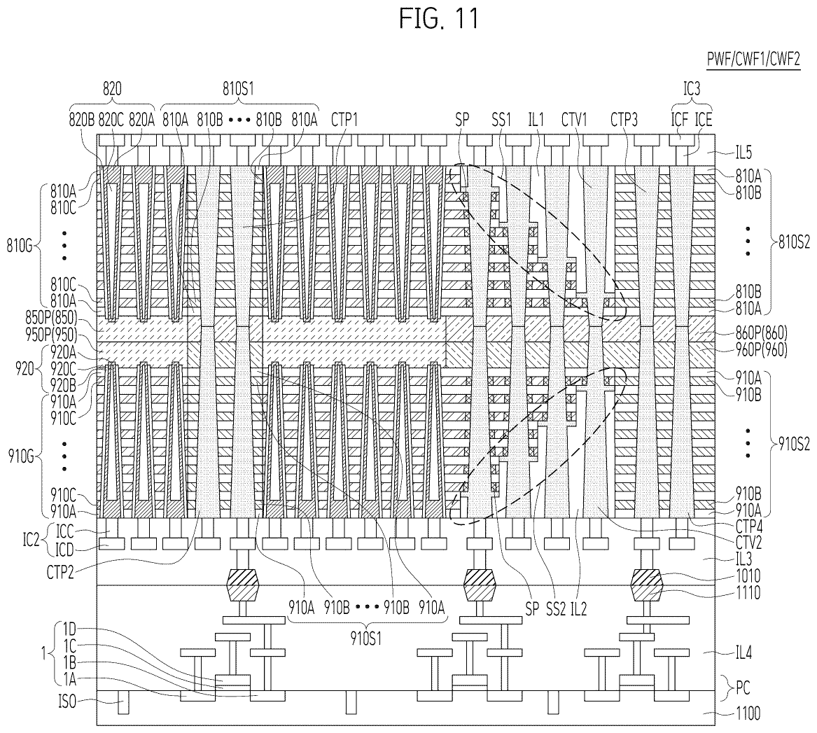

Referring to FIG. 11, a peripheral circuit wafer PWF may be formed, for example, by using the method of forming the peripheral circuit wafer PWF of FIG. 6. For example, the peripheral circuit wafer PWF including a third substrate 1100, a fourth interlayer insulating layer IL4, a peripheral circuit PC, a second interconnection structure IC2, and second peripheral circuit bonding pads 1110 may be formed. The second interconnection structure IC2 may include second vias ICC and second wiring lines ICD. The second peripheral circuit bonding pads 1110 may each include a conductive material such as copper.

Subsequently, the second cell wafer CWF2 and the peripheral circuit wafer PWF may be bonded to each other. For example, the first peripheral circuit bonding pads 1010 of the second cell wafer CWF2 and the second peripheral circuit bonding pads 1110 of the peripheral circuit wafer PWF may be directly bonded to each other.

Subsequently, a third interconnection structure IC3 may be formed. The third interconnection structure IC3 may be formed in a fifth interlayer insulating layer IL5, and may include third vias ICE and third wiring lines ICF.

According to the manufacturing method described above, not only the first dielectric bonding pattern 860P and the second dielectric bonding pattern 960P, but also the first source bonding pattern 850P and the second source bonding pattern 950P may be used as the bonding structures. Here, the first channel structures 820 and the second channel structures 920 may share the first source bonding pattern 850P and the second source bonding pattern 950P as the source structures with each other. The first source bonding pattern 850P and the second source bonding pattern 950P may be used as both the bonding structures and the source structures.

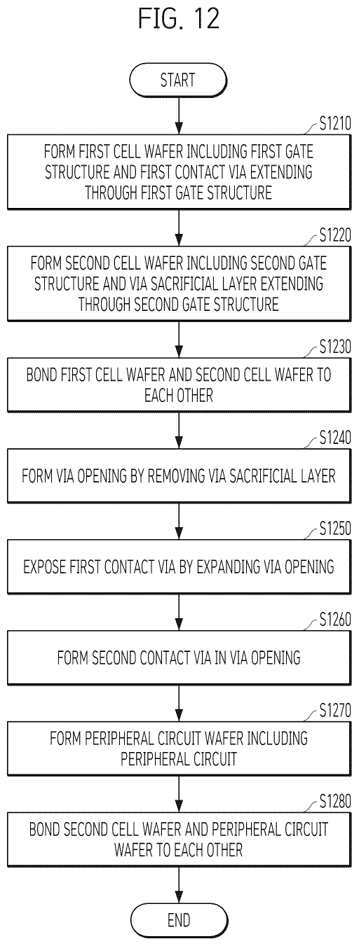

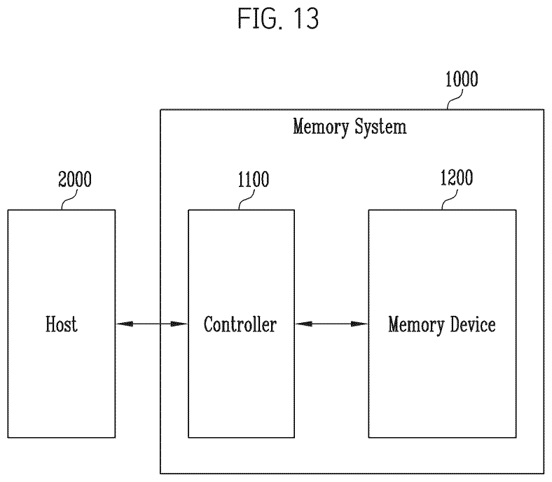

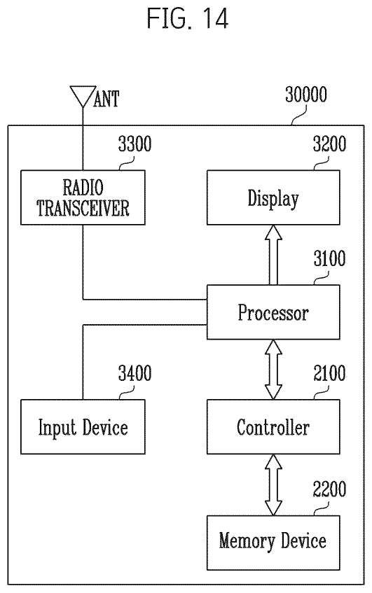

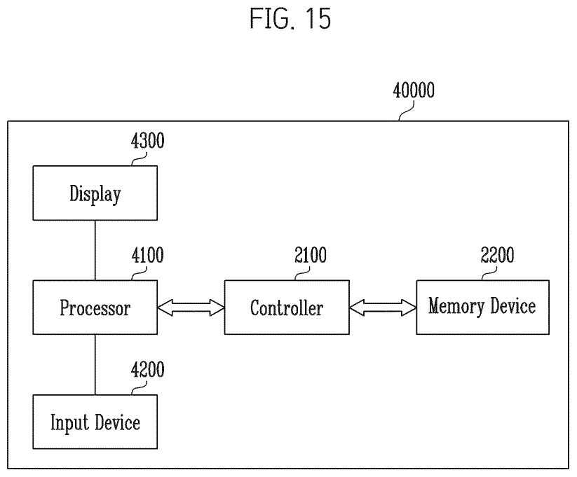

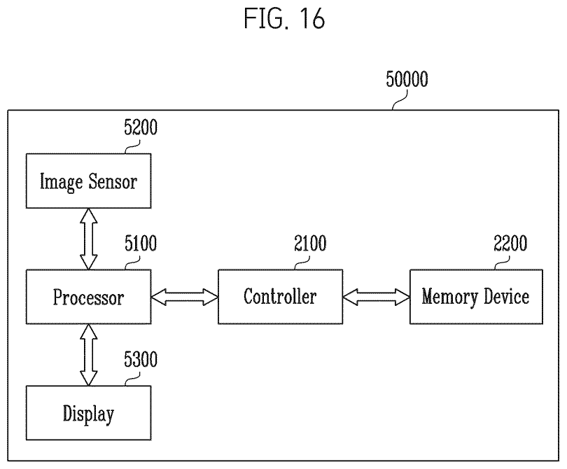

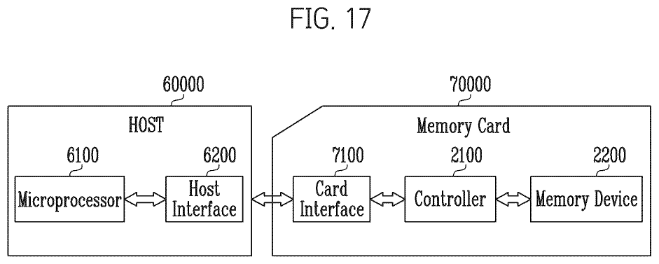

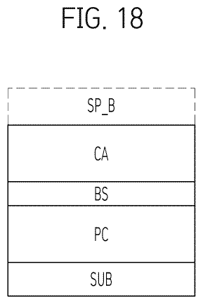

FIG. 12 is a flowchart describing a manufacturing method of a semiconductor device in accordance with FIGS. 3A and 3B, FIG. 4, FIGS. 5A to 5C, and FIGS. 6 and 7, and FIGS. 8 to 11. Hereinafter, content overlapping with previously described content may be omitted.

Referring to FIGS. 3A, 3B, 8, and 12, the first cell wafer CWF1 may be formed. For example, the first cell wafer CWF1 including the first gate structure 310G or 810G and the first contact via CTV1 extending through the first gate structure 310G or 810G may be formed (S1210). The first cell wafer CWF1 may further include the first source structure 350P and the first dielectric bonding layer 360 formed on the first source structure 350P. Alternatively, the first cell wafer CWF1 may further include the first source bonding pattern 850P and the first dielectric bonding pattern 860P formed at substantially the same level as the first source bonding pattern 850P.

Referring to FIGS. 4, 9, and 12, the second cell wafer CWF2 may be formed. For example, the second cell wafer CWF2 including the second gate structure 410G or 910G and the via sacrificial layer CTVS extending through the second gate structure 410G or 910G may be formed (S1220). Here, the second cell wafer CWF2 may further include the second source structure 450P and the second dielectric bonding layer 460 formed on the second source structure 450P. Alternatively, the second cell wafer CWF2 may further include the second source bonding pattern 950P and the second dielectric bonding pattern 960P formed at substantially the same level as the second source bonding pattern 950P.

Subsequently, referring to FIGS. 5A, 10, and 12, the first cell wafer CWF1 and the second cell wafer CWF2 may be bonded to each other (S1230). For example, the first dielectric bonding layer 360 of the first cell wafer CWF1 and the second dielectric bonding layer 460 of the second cell wafer CWF2 may be directly bonded to each other. Alternatively, the first dielectric bonding pattern 860P of the first cell wafer CWF1 and the second dielectric bonding pattern 960P of the second cell wafer CWF2 may be directly bonded to each other, and the first source bonding pattern 850P of the first cell wafer CWF1 and the second source bonding pattern 950P of the second cell wafer CWF2 may be directly bonded to each other.

Subsequently, referring to FIGS. 5B, 11, and 12, the via opening CTVOP may be formed by removing the via sacrificial layer CTVS of the second cell wafer CWF2 (S1240). Subsequently, the first contact via CTV1 of the first cell wafer CWF1 may be exposed by expanding the via opening CTVOP (S1250). For example, the first contact via CTV1 may be exposed by etching the first dielectric bonding layer 360 of the first cell wafer CWF1 and the second dielectric bonding layer 460 of the second cell wafer CWF2. Alternatively, the first contact via CTV1 may be exposed by etching the first dielectric bonding pattern 860P of the first cell wafer CWF1 and the second dielectric bonding pattern 960P of the second cell wafer CWF2.

Subsequently, the second contact via CTV2 may be formed in the via opening CTVOP (S1260). For example, the second contact via CTV2 directly connected to the first contact via CTV1 may be formed. Here, a via connection portion where the first contact via CTV1 and the second contact via CTV2 are connected to each other may be disposed on the dielectric bonding layer 460. Alternatively, the via connection portion may be disposed in the second dielectric bonding pattern 960P.

Subsequently, referring to FIGS. 5C, 6, 11, and 12, the peripheral circuit wafer PWF including the peripheral circuit PC may be formed (S1270). Here, the second cell wafer CWF2 may further include the first peripheral circuit bonding pads 510 or 1010, and the peripheral circuit wafer PWF may further include the second peripheral circuit bonding pads 610 or 1110. The first peripheral circuit bonding pads 510 or 1010 and the second peripheral circuit bonding pads 610 or 1110 may each include a conductive material such as copper. Subsequently, the second cell wafer CWF2 and the peripheral circuit wafer PWF may be bonded to each other (S1280). For example, the first peripheral circuit bonding pads 510 or 1010 of the second cell wafer CWF2 and the second peripheral circuit bonding pads 610 or 1110 of the peripheral circuit wafer PWF may be directly bonded to each other.

According to the manufacturing method described above, before the second cell wafer CWF2 and the peripheral circuit wafer PWF are bonded to each other, the first source structure 350P or the first source bonding pattern 850P of the first cell wafer CWF1 may be formed in advance and the second source structure 450P or the second source bonding pattern 950P of the second cell wafer CWF2 may be formed in advance. Before the first peripheral circuit bonding pads 510 or 1010 and the second peripheral circuit bonding pads 610 or 1110 each including copper or the like are formed, the first source structure 350P and the second source structure 450P or the first source bonding pattern 850P and the second source bonding pattern 950P may be formed. Accordingly, an annealing process required for forming the first source structure 350P and the second source structure 450P or the first source bonding pattern 850P and the second source bonding pattern 950P may be performed without being restricted by the first peripheral circuit bonding pads 510 or 1010 and the second peripheral circuit bonding pads 610 or 1110 each including copper or the like which are vulnerable to heat.

In addition, the first dielectric bonding layer 360 of the first cell wafer CWF1 and the second dielectric bonding layer 460 of the second cell wafer CWF2 may be bonded to each other. Alternatively, the first source bonding pattern 850P and the first dielectric bonding pattern 860P of the first cell wafer CWF1 may be bonded to the second source bonding pattern 950P and the second dielectric bonding pattern 960P of the second cell wafer CWF2, respectively. In such a case, in order to electrically connect the first cell wafer CWF1 and the second cell wafer CWF2 to each other, after the via opening CTVOP is formed by removing the via sacrificial layer CTVS of the second cell wafer CWF2, the first contact via CTV1 of the first cell wafer CWF1 may be exposed by expanding the via opening CTVOP, and the second contact via CTV2 connected to the first contact via CTV1 may be formed in the via opening CTVOP.

For reference, it has been described in FIG. 12 that the first cell wafer CWF1 is formed (S1210), the second cell wafer CWF2 is formed (S1220), and the peripheral circuit wafer PWF is formed (S1270), but the order of forming the first cell wafer CWF1, the second cell wafer CWF2, and the peripheral circuit wafer PWF is not limited thereto. For example, it is also possible to form the peripheral circuit wafer PWF and then form the first cell wafer CWF1 and the second cell wafer CWF2. Alternatively, it is also possible to form the first cell wafer CWF1, the second cell wafer CWF2, and the peripheral circuit wafer PWF at the same time. Namely, the order of the manufacturing method of a semiconductor device according to an embodiment of the present disclosure is not limited to that described in FIGS. 3A and 3B, FIG. 4, FIGS. 5A to 5C, and FIGS. 6 and 7, and FIGS. 8 to 11.

FIG. 13 is a diagram illustrating a memory system according to an embodiment of the present disclosure.

Referring to FIG. 13, the memory system 1000 may include a memory device 1200 for storing data, and a controller 1100 communicating between the memory device 1200 and a host 2000.

The host 2000 may store data in and/or retrieve data from the memory system 1000. In operation, the host 2000 may generate a request for one or more of various operations and may output the generated request to the memory system 1000. For example, the request may include a program request for a program operation, a read request for a read operation, an erase request for an erase operation, and the like. The host 2000 may communicate with the memory system 1000 through an interface such as a peripheral component interconnect express (PCIe), an advanced technology attachment (ATA), a serial ATA (SATA), a parallel ATA (PATA), a serial attached SCSI (SAS), a non-volatile memory express (NVMe), a universal serial bus (USB), a multi-media card (MMC), an enhanced small disk interface (ESDI), or integrated drive electronics (IDE).

The host 2000 may include at least one of a computer, a portable digital device, a tablet, a digital camera, a digital audio player, a television, a wireless communication device, or a cellular phone, but embodiments of the present disclosure are not limited thereto.

The controller 1100 may generally control an operation of the memory system 1000. The controller 1100 may control the memory device 1200 according to a request received from the host 2000. The controller 1100 may control the memory device 1200 so that the program operation, the read operation, the erase operation, and the like may be performed according to a request from the host 2000. Alternatively, the controller 1100 may perform a background operation or the like for improving performance of the memory system 1000 even without a request from the host 2000.

The controller 1100 may transmit a control signal and a data signal to the memory device 1200 for controlling the operation of the memory device 1200. The control signal and the data signal may be transmitted to the memory device 1200 through different input/output lines. The data signal may include a command, an address, or data. The control signal may be used to divide a section in which the data signal is input.

The memory device 1200 may perform the program operation, the read operation, the erase operation, and the like under control of the controller 1100. The memory device 1200 may be implemented as a volatile memory device in which stored data is destroyed when power supply is cut off, or a non-volatile memory device in which stored data is maintained even though power supply is cut off.

The memory device 1200 may be a semiconductor device having the structure previously described with reference to FIGS. 1, and 2. The memory device 1200 may be the semiconductor device manufactured using the manufacturing method previously described with reference to FIGS. 3a to 7, 8 to 11 and 12. In an embodiment, a semiconductor device may include a peripheral circuit; a first gate structure disposed over the peripheral circuit; a second gate structure disposed over the first gate structure; a dielectric bonding structure extending between the first gate structure and the second gate structure; a first contact via extending through the first gate structure and extending into the dielectric bonding structure; a second contact via extending through the second gate structure and connected to the first contact via; and a peripheral circuit bonding structure electrically connecting the first contact via and the peripheral circuit to each other.

FIG. 14 is a diagram illustrating a memory system according to an embodiment of the present disclosure.

Referring to FIG. 14, the memory system 30000 may be implemented as a cellular phone, a smart phone, a tablet, a personal computer (PC), a personal digital assistant (PDA), or a wireless communication device. The memory system 30000 may include a memory device 2200 and a controller 2100 capable of controlling an operation of the memory device 2200.

The controller 2100 may control a data access operation, for example, a program operation, an erase operation, a read operation, or the like, of the memory device 2200 under control of a processor 3100.

Data programmed in the memory device 2200 may be output through a display 3200 under the control of the controller 2100.

A radio transceiver 3300 may transmit and receive a radio signal through an antenna ANT. For example, the radio transceiver 3300 may convert the radio signal received through the antenna ANT into a signal that may be processed by the processor 3100. Therefore, the processor 3100 may process the signal output from the radio transceiver 3300 and transmit the processed signal to the controller 2100 or the display 3200. The controller 2100 may transmit the signal processed by the processor 3100 to the memory device 2200. In addition, the radio transceiver 3300 may convert a signal output from the processor 3100 into the radio signal, and output the converted radio signal to an external device through the antenna ANT. An input device 3400 may be a device capable of inputting a control signal for controlling an operation of the processor 3100 or data to be processed by the processor 3100, and may be implemented as a pointing device such as a touch pad or a computer mouse, a keypad, or a keyboard. The processor 3100 may control an operation of the display 3200 so that data output from the controller 2100, data output from the radio transceiver 3300, or data output from the input device 3400 is output through the display 3200.

According to an embodiment, the controller 2100 capable of controlling an operation of memory device 2200 may be implemented as a part of the processor 3100 and may be implemented as a chip separate from the processor 3100.

FIG. 15 is a diagram illustrating a memory system according to an embodiment of the present disclosure.

Referring to FIG. 15, the memory system 40000 may be implemented as a personal computer (PC), a tablet, a net-book, an e-reader, a personal digital assistant (PDA), a portable multimedia player (PMP), an MP3 player, or an MP4 player.

The memory system 40000 may include the memory device 2200 and the controller 2100 capable of controlling a data process operation of the memory device 2200.

A processor 4100 may output data stored in the memory device 2200 through a display 4300, according to data input through an input device 4200. For example, the input device 4200 may be implemented as a pointing device such as a touch pad or a computer mouse, a keypad, or a keyboard.

The processor 4100 may control an overall operation of the memory system 40000 and control an operation of the controller 2100. According to an embodiment, the controller 2100 capable of controlling the operation of memory device 2200 may be implemented as a part of the processor 4100 or may be implemented as a chip separate from the processor 4100.

FIG. 16 is a diagram illustrating a memory system according to an embodiment of the present disclosure.

Referring to FIG. 16, the memory system 50000 may be implemented as an image processing device, for example, a digital camera, a portable phone provided with a digital camera, a smart phone provided with a digital camera, or a tablet provided with a digital camera.

The memory system 50000 includes the memory device 2200 and the controller 2100 capable of controlling a data process operation, for example, a program operation, an erase operation, or a read operation, of the memory device 2200.

An image sensor 5200 of the memory system 50000 may convert an optical image into digital signals, and the converted digital signals may be transmitted to a processor 5100 or the controller 2100. Under control of the processor 5100, the converted digital signals may be output through a display 5300 or stored in the memory device 2200 through the controller 2100. In addition, data stored in the memory device 2200 may be output through the display 5300 under the control of the processor 5100 or the controller 2100.

According to an embodiment, the controller 2100 capable of controlling the operation of memory device 2200 may be implemented as a part of the processor 5100 or may be implemented as a chip separate from the processor 5100.

FIG. 17 is a diagram illustrating a memory system according to an embodiment of the present disclosure.

Referring to FIG. 17, the memory system 70000 may be implemented as a memory card or a smart card. The memory system 70000 may include the memory device 2200, the controller 2100, and a card interface 7100.

The controller 2100 may control exchange of data between the memory device 2200 and the card interface 7100. According to an embodiment, the card interface 7100 may be a secure digital (SD) card interface or a multi-media card (MMC) interface, but is not limited thereto.

The card interface 7100 may interface data exchange between a host 60000 and the controller 2100 according to a protocol of the host 60000. According to an embodiment, the card interface 7100 may support a universal serial bus (USB) protocol, and an interchip (IC)-USB protocol. Here, the card interface 7100 may refer to hardware capable of supporting a protocol that is used by the host 60000, software installed in the hardware, or a signal transmission method.

When the memory system 70000 is connected to a host interface 6200 of the host 60000 such as a PC, a tablet, a digital camera, a digital audio player, a mobile phone, a console video game hardware, or a digital set-top box, the host interface 6200 may perform data communication with the memory device 2200 through the card interface 7100 and the controller 2100 under control of a microprocessor 6100.

FIG. 18 is a configuration diagram of a semiconductor device according to an embodiment of the present disclosure.

Referring to FIG. 18, the semiconductor device may include a substrate SUB, a peripheral circuit PC, a bonding structure BS, and a memory cell array CA. Here, the peripheral circuit PC and the memory cell array CA may be respectively formed over separate substrates and then bonded. The semiconductor device may further include a support base SP_B.

The substrate SUB may include a semiconductor material. In an embodiment, the semiconductor material may include at least one of a group IV semiconductor, a group III-V compound semiconductor, and a group II-VI compound semiconductor. Here, the group IV semiconductor may include single crystalline silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductors may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well area doped with an n-type impurity and/or a p-well area doped with a p-type impurity.

The substrate SUB may be used as a support in a process of forming the peripheral circuit PC. Here, the peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transmitting an operation voltage and may include a contact plug, a line, and the like.

The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by a bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding interface, and the like. The bonding pad may include a metal and/or an alloy such as copper and aluminum. The bonding interface may include a non-metal-non-metal interface, a metal-metal interface, or the like. The memory cell array CA and the peripheral circuit PC may be electrically connected by the bonding structure BS.

For reference, the interconnection structure included in the cell array CA and/or the peripheral circuit PC may also be used as the bonding structure BS. In an embodiment, the interconnection structure included in the cell array CA and the interconnection structure included in the peripheral circuit PC may be directly bonded. In this case, a bit line, source line, or the like may be used as the bonding structure without a separate bonding pad.

The semiconductor device may also have a structure that combines the embodiments previously described with reference to FIGS. 1 and 2 or have a partially modified structure. At least one memory cell array CA and/or at least one peripheral circuit PC may be additionally bonded to the embodiment described with reference to FIGS. 1 and 2. For example, a third wafer including the memory cell array CA may be additionally manufactured, and then the third wafer may be bonded to the first wafer including the memory cell array CA. Here, the bonding structure BS may be for connecting the memory cell array CA and the memory cell array CA.

Although embodiments according to the technical idea of the present disclosure have been described above with reference to the accompanying drawings, this is only for describing the embodiments according to the concepts of the present disclosure, and the present disclosure is not limited to the above embodiments. Various types of substitutions, modifications, and changes for the embodiments may be made by those skilled in the art, to which the present disclosure pertains, without departing from the technical scope of the present disclosure defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a peripheral circuit;
a first gate structure disposed over the peripheral circuit;
a second gate structure disposed over the first gate structure;
a dielectric bonding structure disposed between the first gate structure and the second gate structure;
a first contact via extending through the first gate structure and extending into the dielectric bonding structure;
a second contact via extending through the second gate structure and connected to the first contact via; and
a peripheral circuit bonding structure electrically connecting the first contact via and the peripheral circuit to each other.

2. The semiconductor device of claim 1, further comprising:
a first source structure disposed on the first gate structure;
a second source structure disposed between the first source structure and the second gate structure;
first channel structures extending into the first source structure through the first gate structure; and
second channel structures extending into the second source structure through the second gate structure.

3. The semiconductor device of claim 2, wherein the dielectric bonding structure extends between the first source structure and the second source structure.

4. The semiconductor device of claim 1, wherein the first gate structure includes a first staircase structure,
the second gate structure includes a second staircase structure,
the first contact via extends through the first staircase structure and extends into the dielectric bonding structure, and
the second contact via extends through the second staircase structure and is connected to the first contact via.

5. The semiconductor device of claim 4, wherein the first gate structure includes first conductive layers,
the second gate structure includes second conductive layers,
the first contact via is connected to at least one of the first conductive layers, and
the second contact via is connected to at least one of the second conductive layers.

6. The semiconductor device of claim 5, wherein the first conductive layer connected to the first contact via is an uppermost first conductive layer of the first staircase structure among the first conductive layers, and
the second conductive layer connected to the second contact via is an uppermost second conductive layer of the second staircase structure among the second conductive layers.

7. The semiconductor device of claim 1, wherein a via connection portion where the first contact via and the second contact via are connected to each other is disposed over the dielectric bonding structure.

8. The semiconductor device of claim 1, wherein the dielectric bonding structure includes a first dielectric bonding layer and a second dielectric bonding layer disposed on the first dielectric bonding layer.

9. The semiconductor device of claim 8, wherein the first dielectric bonding layer and the second dielectric bonding layer are directly bonded to each other.

10. The semiconductor device of claim 1, wherein the peripheral circuit bonding structure includes a first peripheral circuit bonding pad and a second peripheral circuit bonding pad disposed on the first peripheral circuit bonding pad.

11. The semiconductor device of claim 1, further comprising:
a first stack disposed at a level corresponding to the first gate structure;
a second stack disposed at a level corresponding to the second gate structure;
a first contact plug extending through the first stack and extending into the dielectric bonding structure; and
a second contact plug extending through the second stack and connected to the first contact plug.

12. The semiconductor device of claim 11, wherein a plug connection portion where the first contact plug and the second contact plug are connected to each other is disposed on the dielectric bonding structure.

13. The semiconductor device of claim 1, further comprising:
a source bonding structure disposed between the first gate structure and the second gate structure;
first channel structures extending into the source bonding structure through the first gate structure; and
second channel structures extending into the source bonding structure through the second gate structure.

14. The semiconductor device of claim 13, wherein the dielectric bonding structure is disposed at a level corresponding to the source bonding structure.

15. The semiconductor device of claim 14, wherein the dielectric bonding structure includes a first dielectric bonding pattern and a second dielectric bonding pattern disposed on the first dielectric bonding pattern.

16. The semiconductor device of claim 15, wherein the first dielectric bonding pattern and the second dielectric bonding pattern are directly bonded to each other.

17. The semiconductor device of claim 15, wherein a via connection portion where the first contact via and the second contact via are connected to each other is disposed in the second dielectric bonding pattern.

18. The semiconductor device of claim 13, wherein the source bonding structure includes a first source bonding pattern and a second source bonding pattern disposed on the first source bonding pattern.

19. The semiconductor device of claim 18, wherein the first source bonding pattern and the second source bonding pattern are directly bonded to each other.

20. The semiconductor device of claim 13, further comprising:
a first stack disposed at a level corresponding to the first gate structure;
a second stack disposed at a level corresponding to the second gate structure;
a first contact plug extending through the first stack and extending into the dielectric bonding structure; and
a second contact plug extending through the second stack and connected to the first contact plug.

21. The semiconductor device of claim 20, wherein a plug connection portion where the first contact plug and the second contact plug are connected to each other is disposed in the dielectric bonding structure.
